(19) United States
(12) Patent Application Publication
(10) Pub. No.: US 2025/0092504 A1
(43) Pub. Date: Mar. 20, 2025

(54) Metal Image Forming Method

(71) Applicant: ePrint Laboratories Co., Ltd., Tokyo (JP)

(72) Inventors: Yuji Mitani, Tokyo (JP); Kazuhiko Honjyo, Tokyo (JP); Takashi Tomie, Tokyo (JP)

(73) Assignee: ePrint Laboratories Co., Ltd., Tokyo (JP)

(21) Appl. No.: 18/887,364

(22) Filed: Sep. 17, 2024

(30) Foreign Application Priority Data
Sep. 19, 2023 (JP) 2023-173917
Sep. 19, 2023 (JP) 2023-173918
Dec. 26, 2023 (JP) 2023-223921

(51) Int. Cl. C23C 14/04; G03F 7/00; G03G 15/02; G03G 15/16; G03G 15/18

(52) U.S. Cl. CPC C23C 14/042; G03F 7/0002; G03G 15/0291; G03G 15/1625; G03G 15/18

(57) ABSTRACT

The metal image forming method of the invention utilizes a toner image as a resist pattern for metal image formation in a publicly known lift-off process, instead of using the toner image as a resist pattern during etching steps. A toner image is formed by formation and development of an electrostatic pattern directly on the substrate, without using a photosensitive body. The original toner image-formed surface, or the toner image-transferred surface, is covered with a metal layer by a physical vapor deposition method, after which the toner image is removed together with the metal layer on the toner image, to obtain a metal image. Transfer of a resin image onto a curved substrate, covering of the resin image-transferred surface with a metal layer by a physical vapor deposition method, and subsequent removal of the resin image together with the metal layer on the resin image, allows formation of a high-definition metal image on the curved substrate.

### FIELD

The present invention relates to a metal image forming method.

### BACKGROUND

A widely used method for forming metal images is the subtractive method. The steps used in a subtractive method can be summarized as follows. First, a metal image is formed by a step of laminating a photosensitive and etching resistant resist onto a metal layer of an object provided with a metal layer on an insulating substrate (resist laminating step), a step of exposing the resist layer through a photomask and then developing it to form a resist pattern on the metal layer (resist pattern forming step), a step of removal by etching of the metal layer not covered by the resist layer, and then washing (etching step), and a step of removing the resist layer from the metal layer and then washing to obtain a metal image (resist removal step).

The subtractive method requires large-scale exposure equipment and developing equipment in the resist pattern forming step, and also production and storage of the photomask is costly. Methods using toner images formed on photosensitive bodies as resist patterns have been proposed as a means of solving these problems (see PTL 1). Specifically, a toner image formed on a photosensitive body using etching-resistant wet toner is transferred onto a conductive layer (such as a copper foil or ITO film) of an object by electrostatic transfer to form and fix a resist pattern on the conductive layer. Following resist pattern formation, a conductive layer image is formed by steps of etching and resist removal.

Substrates with such metal images formed are utilized in products such as touch panels, EL lights, electromagnetic shields, antennas and heating units, but most such substrates have flat or gently curved surfaces. This is because wire breakage may occur with molding of metal images to give them large curvature. One proposed solution is a method of creating a drawing plate having an electrode layer with multiple electrode areas formed on a thermoplastic resin flat plate using electroconductive ink comprising a conductive substance and a binder, and heating, softening, molding and cooling the drawing plate to produce a capacitive touch panel with a curved touch surface (see PTL 2, for example). While electroconductive ink is resistant to wire breakage during molding, it has been problematic due to low conductivity, which prevents formation of fine wirings, and poor transparency, as compared to metal images. A second proposed solution is to first provide a catalyst layer on a transparent substrate surface made of a thermoplastic resin, and then to form on the catalyst layer a shielding layer with numerous fine line grooves of depth reaching to the surface of the catalyst layer. And then, it is to form all or part of the transparent base material as a curved surface, and then carry out metal-plated treatment to form thin conductive metal wires in fine line grooves (see PTL 3, for example). Thermoplastic resin substrates with metal images formed by this method have improved transparency.

### CITATION LIST

PTL 1: Japanese Unexamined Patent Publication No. 2008-270398
PTL 2: Japanese Unexamined Patent Publication No. 2012-242871
PTL 3: Japanese Unexamined Patent Publication No. 2023-94084

### SUMMARY

### Technical Problem

The aforementioned methods using toner images formed on photosensitive bodies as resist patterns are able to reduce equipment cost, production cost and production time for the resist pattern forming step. However, an etching step is still required. Large-scale equipment is also necessary for the etching step, resulting in increased production cost and production time. A new metal image forming method is desired which can eliminate the etching step as well as the resist pattern forming step.

There is demand in the relevant field for panels made of thermosetting resins, UV curable resins, glass and ceramics with curved surfaces forming metal images, from the viewpoint of product reliability and designability. However, both of the solutions described above assume the use of thermoplastic resins as substrate materials, which fails to satisfactorily meet this demand.

The present invention proposes a metal image forming method designed to solve the aforementioned problem.

### Solution to Problem

The present inventors studied using toner images as resist patterns for metal image formation in the publicly known lift-off process, instead of using toner images as resist patterns during etching steps. This led to the finding that a metal image can be obtained on the insulating layer of a substrate having an insulating layer and conductive layer, without using a photosensitive body, by directly forming an electrostatic pattern on the insulating layer, developing the electrostatic pattern with charged particles known as “toner” to form a toner image on the insulating layer, covering the toner image-formed surface with a metal layer by a physical vapor deposition method, and then removing the toner image together with the metal layer on the toner image, and the present invention has been devised on the basis of this finding (first invention).

Moreover, it was found that if an electrostatic pattern is directly formed on the release layer of a substrate (S) comprising a release layer, an insulating layer and a conductive layer, without using a photosensitive body, and a toner image is formed on the release layer by developing the electrostatic pattern with charged particles known as “toner”, then the toner image can later be transferred onto any substrate T, allowing a metal image to be obtained on the substrate (T) by covering of the surface of the substrate (T) onto which the toner image has been transferred, with a metal layer by a physical vapor deposition method, and then removing the toner image together with the metal layer on the toner image, and the present invention was further devised on the basis of this finding (second invention).

It was further found that if the substrate (T) itself, previously molded into a curved shape, is used as the molding die for molding of a resin image-formed substrate (S) and sticking it onto the substrate (T), it is possible to transfer the resin image onto the curved substrate (T), and further that by covering the resin image-transferred surface of the substrate (T) with a metal layer by a physical vapor deposition method and then removing the resin image together with the metal layer on the resin image, it is possible to form a high-definition metal image on the curved substrate (T) composed of a thermosetting resin, UV curable resin, glass or ceramic, and the present invention was further devised on this basis (third invention).

The present invention achieves the object described above by the following means.

<1> A metal image forming method, comprising:
(1) forming an electrostatic pattern on the insulating layer of a substrate (S) having an insulating layer and a conductive layer (hereunder referred to as “electrostatic pattern-forming step”),
(2) developing the electrostatic pattern with charged particles known as toner, to form a toner image on the insulating layer of the substrate (S) (hereunder referred to as “developing step”),
(3) covering the toner image-formed surface of the substrate (S) with a metal layer by a physical vapor deposition method (hereunder referred to as “metal layer-covering step”), and
(4) removing the toner image together with the metal layer on the toner image (hereunder referred to as “toner-removing step”).

<2> The metal image forming method according to <1>, wherein in step (1), an original plate having a plate layer (which has built-in a letterpress, an intaglio plate, or a gravure plate pattern) and a first electrode, and a substrate (S) having an insulating layer and a conductive layer as a second electrode, are used, closely bonding the plate layer of the original plate with the insulating layer of the substrate (S), and a voltage sufficient to cause discharge in the space between the pattern of the plate layer and the insulating layer is applied between the first electrode of the original plate and the second electrode of the substrate (S), thereby forming an electrostatic pattern corresponding to the pattern of the plate layer on the insulating layer of the substrate (S).

<3> The metal image forming method according to <1>, wherein in step (1), a mask sheet comprising a molded article consisting of only a conductive material, or a laminated body consisting of an insulating material and a conductive material, and provided with a specified ion permeable opening, is used with a substrate (S) having an insulating layer and a conductive layer as a back electrode, closely bonding together the mask sheet and the insulating layer of the substrate (S), conducting ion irradiation through the mask sheet, and then releasing the mask sheet from the substrate (S), to form an electrostatic pattern corresponding to the ion-permeable opening and ion shielding part of the mask sheet on the insulating layer of the substrate (S).

<4> The metal image forming method according to <3>, wherein the ion irradiation means is an ion irradiation system using corona discharge.

<5> A metal image forming method, comprising:
(1) forming an electrostatic pattern on the release layer of a substrate (S) having a release layer, an insulating layer and a conductive layer (hereunder referred to as “electrostatic pattern-forming step”),
(2) developing the electrostatic pattern with charged particles known as toner, to form a toner image on the release layer of the substrate (S) (hereunder referred to as “developing step”),
(3) transferring the toner image onto the substrate (T) (hereunder referred to as “toner transfer step”),
(4) covering the toner image-transferred surface of the substrate (T) with a metal layer by a physical vapor deposition method (hereunder referred to as “metal layer-covering step”), and
(5) removing the toner image together with the metal layer on the toner image (hereunder referred to as “toner-removing step”).

<6> The metal image forming method according to <5>, wherein in step (1) of <5>, an original plate having a plate layer (which has built-in a letterpress, an intaglio plate, or a gravure plate pattern) and a first electrode, and a substrate (S) having a release layer, an insulating layer and a conductive layer as a second electrode, are used, closely bonding the plate layer of the original plate with the release layer of the substrate (S), and a voltage sufficient to cause discharge in the space between the pattern of the plate layer and the release layer is applied between the first electrode of the original plate and the second electrode of the substrate (S), thereby forming an electrostatic pattern corresponding to the pattern of the plate layer on the release layer of the substrate (S).

<7> The metal image forming method according to <5>, wherein in step (1) of <5>, a mask sheet comprising a molded article consisting of only a conductive material, or a laminated body consisting of an insulating material and a conductive material, and provided with a specified ion permeable opening, is used with a substrate (S) having a release layer, an insulating layer and a conductive layer as a back electrode, closely bonding together the mask sheet and the release layer of the substrate (S), conducting ion irradiation through the mask sheet, and then releasing the mask sheet from the substrate (S), to form an electrostatic pattern corresponding to the ion-permeable opening and ion shielding part of the mask sheet on the release layer of the substrate (S).

<8> The metal image forming method according to <7>, wherein the ion irradiation means is an ion irradiation system using corona discharge.

<9> A metal image forming method, comprising:
(1) forming a resin image on a flat substrate (S) (hereunder referred to as “resin image-forming step”),
(2) molding the substrate (S) so that the resin image surface of the substrate (S) is closely bonded to the substrate (T) having all or part of curved surface, to transfer the resin image onto the substrate (T) (hereunder referred to as “resin image transfer step”),
(3) covering the resin image-transferred surface of the substrate (T) with a metal layer by a physical vapor deposition method (hereunder referred to as “metal layer-covering step”), and
(4) removing the resin image together with the metal layer on the resin image (hereunder referred to as “resin image-removing step”).

<10> The metal image forming method according to <9>, wherein in step (1) of <9>, the flat substrate (S) is made of an insulating layer composed of a thermoplastic resin film or sheet, or a composite thereof, and a release layer formed on one side of the insulating layer, and a resin image is formed on the release layer by a printing method.

<11> The metal image forming method according to <9>, wherein in step (1) of <9>, the flat substrate (S) is made of an insulating layer composed of a thermoplastic resin film or sheet, or a composite thereof, a release layer formed on one side of the insulating layer, and a conductive layer provided on the opposite side from the release layer, and an electrostatic pattern is first formed on the release layer, after which the electrostatic pattern is developed by charged particles known as toner to form a resin image on the release layer.

<12> The metal image forming method according to <11>, wherein an original plate having a plate layer (which has built-in a letterpress, an intaglio plate, or a gravure plate pattern) and a first electrode, and a substrate (S) having a release layer, an insulating layer and a conductive layer as a second electrode, are used, closely bonding the plate layer of the original plate with the release layer of the substrate (S), and a voltage sufficient to cause discharge in the space between the pattern of the plate layer and the release layer is applied between the first electrode of the original plate and the second electrode of the substrate (S), thereby forming an electrostatic pattern corresponding to the pattern of the plate layer on the release layer of the substrate (S).

<13> The metal image forming method according to <11>, wherein a mask sheet comprising a molded article consisting of only a conductive material, or a laminated body consisting of an insulating material and a conductive material, and provided with a specified ion permeable opening, is used with a substrate (S) having a release layer, an insulating layer and a conductive layer as a back electrode, closely bonding together the mask sheet and the release layer of the substrate (S), conducting ion irradiation through the mask sheet, and then releasing the mask sheet from the substrate (S), to form an electrostatic pattern corresponding to the ion-permeable opening and ion shielding part of the mask sheet on the release layer of the substrate (S).

### Advantageous Effects of Invention

Since the method of the first invention is a metal image forming method with no resist pattern forming step or etching step as in the prior art, the equipment used for those steps is unnecessary, and the production cost and production time required for those steps can be reduced. In the method of the second invention, it is possible to repeat the procedures of transfer of the toner image onto an arbitrary substrate, covering of the toner image-transferred surface with a metal layer and simultaneous removal of the toner image and the metal layer on the toner image, to form a metal image on the arbitrary substrate. In the method of the third invention, the substrate (T) itself, previously molded into a curved shape, is used as a molding die for molding of a resin image-formed substrate (S) and sticking it onto the substrate (T), thus transferring the resin image onto the substrate (T), further covering the resin image-transferred surface of the substrate (T) with a metal layer by a physical vapor deposition method, and then removing the resin image together with the metal layer on the resin image to form a metal image, thereby making it possible to form a high-definition metal image on the curved substrate (T) composed of a thermosetting resin, UV curable resin, glass or ceramic.

### BRIEF DESCRIPTION OF DRAWINGS

FIG. 1 is a diagram illustrating an electrostatic pattern-forming step according to the first invention.

FIG. 2 is a diagram illustrating a developing step according to the first invention.

FIG. 3 is a diagram illustrating a metal layer-covering step according to the first invention.

FIG. 4 is a diagram illustrating a toner-removing step according to the first invention.

FIG. 5 is a diagram illustrating an example of an electrostatic pattern-forming step according to the first invention.

FIG. 6 is a diagram illustrating another example of an electrostatic pattern-forming step according to the first invention.

FIG. 7 is a diagram illustrating an electrostatic pattern-forming step according to the second invention.

FIG. 8 is a diagram illustrating a developing step according to the second invention.

FIG. 9 is a diagram illustrating a toner transfer step according to the second invention.

FIG. 10 is a diagram illustrating a metal layer-covering step according to the second invention.

FIG. 11 is a diagram illustrating a toner-removing step according to the second invention.

FIG. 12 is a diagram illustrating an example of an electrostatic pattern-forming step according to the second invention.

FIG. 13 is a diagram illustrating another example of an electrostatic pattern-forming step according to the second invention.

FIG. 14 is a diagram illustrating an example of a resin image-forming step according to the third invention.

FIG. 15 is a diagram illustrating another example of a resin image-forming step according to the third invention.

FIG. 16 is a diagram illustrating a resin image transfer step for FIG. 14 according to the third invention.

FIG. 17 is a diagram illustrating a resin image transfer step for FIG. 15 according to the third invention.

FIG. 18 is a diagram illustrating a metal layer-covering step according to the third invention.

FIG. 19 is a diagram illustrating an example of a resin image-removing step according to the third invention.

### DESCRIPTION OF EMBODIMENTS

Embodiments of the invention will now be described in detail. It is to be understood, incidentally, that the invention is not limited to the embodiments and may incorporate various modifications within the scope of the gist thereof.

### First Invention

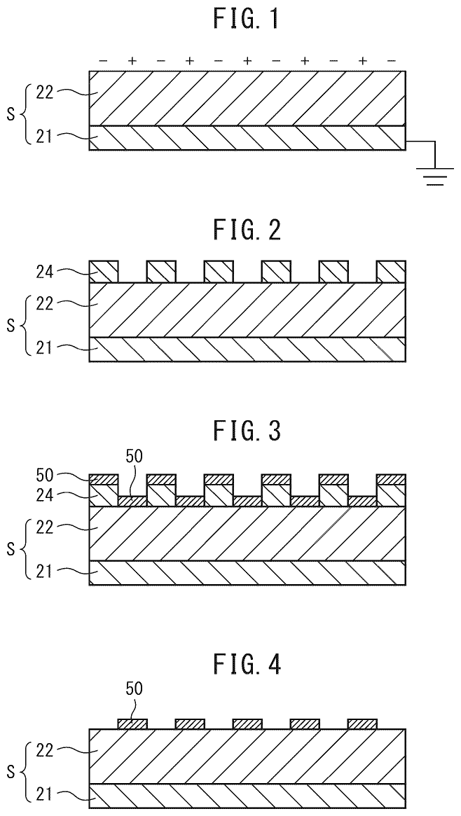

FIG. 1 shows an electrostatic pattern-forming step according to the first invention, in a state with an electrostatic pattern formed and held on an insulating layer (22) of the substrate (S).

The substrate (S) is formed of a conductive layer (21) serving as the electrode in the electrostatic pattern-forming step, and an insulating layer (22).

The insulating layer (22) must have a high electrical insulating property since it must hold the electrostatic pattern. The insulating layer (22) used may be a molded article of a polyimide, polycarbonate, PET (polyethylene terephthalate), cycloolefin polymer, cycloolefin copolymer or fluorine-based resin. The lower limit for the thickness of the insulating layer (22) is preferably 1.5 μm or greater from the viewpoint of electrical insulating properties during formation of the electrostatic pattern and during the period of holding the electrostatic pattern, and it is preferably 5 μm or greater from the viewpoint of handling. The upper limit for the thickness of the insulating layer (22) is preferably 300 μm or smaller. If the thickness of the insulating layer (22) exceeds 300 μm, it can potentially impair application of means such as roll-to-roll systems that are used to enhance productivity.

Since it is sufficient for the conductive layer (21) to carry out the role of providing an electric field in the electrostatic pattern-forming step, or of stabilizing the electrified electrical charge on the insulating layer (22), it may be constructed of any material that is conductive, such as metal, a conductive oxide, carbon, graphite or a conductive polymer.

The conductive layer (21) is situated on the opposite side from the electrostatic pattern-formed side of the insulating layer (22). The conductive layer (21) can perform the aforementioned role if it is contact bonded with the insulating layer (22), but handling during the electrostatic pattern-forming step and developing step will be facilitated if it is integral with the insulating layer (22). The insulating layer (22) and conductive layer (21) can be integrated by forming the conductive layer (21) by a method of sputtering a metal film or conductive oxide film, a method of coating a conducting polymer film, or a method of laminating a metal foil, on the opposite side from the electrostatic pattern-formed side of the insulating layer (22). The insulating layer (22) and conductive layer (21) can also be integrated, conversely, by forming the insulating layer (22) by a coating method on the conductive layer (21) made of a metal foil. Alternatively, a conductive layer-attached sheet provided with a conductive layer (21) such as a metal film, conductive oxide film or conducting polymer film on an insulating material sheet may be laminated onto the opposite side from the electrostatic pattern-formed side of the insulating layer (22), using a pressure-sensitive adhesive layer, to integrate the insulating layer (22) and the conductive layer (21).

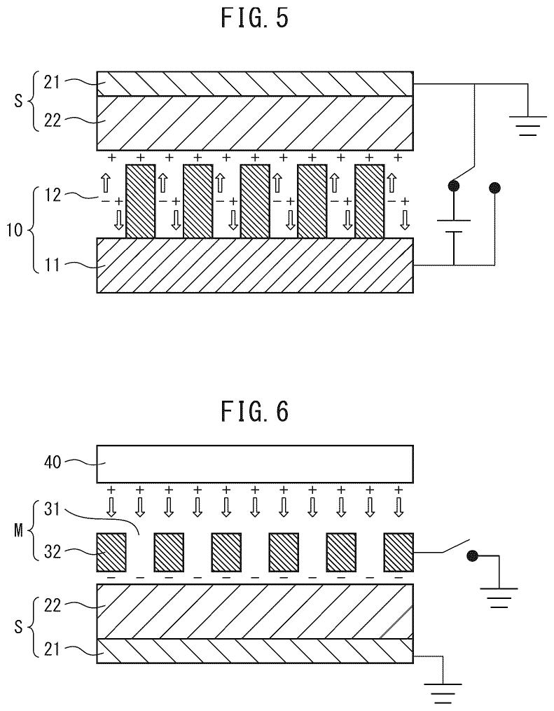

FIG. 5 is an example of an electrostatic pattern-forming step according to the first invention. This method applies a high definition electrostatic printing method previously proposed by the present inventors (see Japanese Patent Application No. 2018-188998). An original plate (10) having a plate layer (12) (which has built-in a letterpress, an intaglio plate, or a gravure plate pattern) (FIG. 5 shows an example of intaglio at locations forming a toner image), and a first electrode (11), and a substrate (S) having an insulating layer (22) and a conductive layer (21) as a second electrode, are used to closely bond the plate layer (12) of the original plate (10) with the insulating layer (22) of the substrate (S), and a voltage sufficient to cause discharge in the space between the pattern of the plate layer (12) and the insulating layer (22) is applied between the first electrode (11) of the original plate (10) and the second electrode (21) of the substrate (S), thereby forming an electrostatic pattern corresponding to the pattern of the plate layer (12) on the insulating layer (22).

The condition of discharge in the space can be calculated by Paschen's law. The discharge starting voltage for a space of 8 μm or greater, assumed to be represented linearly, is approximated by the following formula, where space: d (μm), space discharge starting voltage: Vb.

$$Vb = 312 + 6.2 d \qquad ( 1 )$$

The space (space between the pattern of the plate layer (12) and the insulating layer (22)) is 20 μm and the discharge starting voltage is 436 V. Specifically, if an external voltage of 436 V or higher is applied to the space, discharge takes place and ions are generated. The generated ions are affected by the electric field, with positive ions migrating toward the negative electrode and negative ions migrating toward the positive electrode. The insulating layer (22) is electrified by the ions, acting in a direction to weaken the electric field in the space. Discharge is complete when the voltage applied to the space reaches a discharge starting voltage of 436 V.

In the example shown in FIG. 5, the insulating layer (22) is a PET layer with a thickness of 25 μm and a relative permittivity of 3.2, so that converting to air thickness yields 25÷3.2=7.8. For this example, preliminary charging treatment was carried out at +300 V on the entire surface of the insulating layer (22). The substrate (S) was firmly and closely bonded to the original plate (10) by the preliminary charging treatment. With the plate layer (12) and insulating layer (22) in a closely bonded state, and using the second electrode (21) as ground potential, a voltage was applied to −723 V on the first electrode (11). The voltage applied to a space of 20 μm is (723+300)×20+(20+7.8) V=736 V. Since this is greater than the discharge starting voltage of 436 V for a 20 μm space as obtained from formula (1), discharge ions are produced in the space, the negative ions migrating toward the electrode (21) and electrifying the insulating layer (22), while the positive ions flow to the electrode (11). When the insulating layer (22) is electrified to −(736−436)=−300 V, the electric field in the space reaches a discharge starting voltage of 436 V, and discharge therefore stops. When the applied power is then switched OFF bringing the electrode (21) to 0 V, and the substrate (S) is subsequently released from the original plate (10), an electrostatic pattern is created on the insulating layer (22) as the parts corresponding to the voids in the intaglio (the sections forming the toner image) are electrified to −300 V, while the other parts are electrified to +300 V. The electrode (21) is brought to 0 V before releasing in order to produce a condition that prevents discharge upon release, over all parts of the surface.

FIG. 6 shows another example of an electrostatic pattern-forming step according to the first invention. This method applies an electrostatic printing method previously proposed by the present inventors (see Japanese Patent Application No. 2021-132875). A mask sheet (M) comprising a molded article consisting of only a conductive material, or a laminated body consisting of an insulating material and a conductive material, and provided with a specified ion permeable opening, is used with a substrate (S) having an insulating layer (22) and a conductive layer (21) as a back electrode, closely bonding together the mask sheet (M) and the insulating layer (22) of the substrate (S), conducting ion irradiation through the mask sheet (M), and then releasing the mask sheet (M) from the substrate (S), to form an electrostatic pattern corresponding to the ion-permeable opening and ion shielding part of the mask sheet (M) on the insulating layer (22) of the substrate (S).

In the example of FIG. 6, the conductive layer (21) serving as the back electrode is closely bonded to the opposite side from the electrostatic pattern-formed side of the insulating layer (22), with the conductive layer (21) grounded. Before closely bonding the mask sheet (M) with the insulating layer (22), the entire surface of the insulating layer (22) is subjected to preliminary charging treatment at −300 V. Preliminary charging treatment causes the mask sheet (M) to be firmly and closely bonded to the insulating layer (22). Ion irradiation was carried out on the insulating layer (22) through the mask sheet (M) by ion irradiation means (40) while closely bonding the mask sheet (M) provided with an ion-permeable opening (31). After ion irradiation, the ion irradiation part (corresponding to the ion-permeable opening (31) of the mask sheet (M)) of the insulating layer (22) and the mask sheet (M) surface was electrified to +300 V. The mask sheet (M) was released from the insulating layer (22) while grounded. This produced an electrostatic pattern with the ion irradiation part of the insulating layer (22) (the location other than where the toner image will be formed) electrified to +300 V and the non-ion irradiation part of the insulating layer (22) (the location where the toner image will be formed) electrified to −300 V.

FIG. 2 shows a developing step according to the first invention. The electrostatic pattern formed by the electrostatic pattern-forming step is developed with charged particles known as toner. According to the invention, the toner image must be removed in the final step, together with the metal layer on it, and therefore the material is selected in consideration of the solution to be used for removal (an aqueous alkali solution or organic solvent). For example, if the toner is a polyvinyl acetate-based material, the selected solvent may be methanol.

The toner used may also be liquid toner for electrophotography as previously proposed by the present inventors (see Japanese Patent Application No. 2019-209237). Liquid toner is advantageous for formation of higher-resolution toner images than with dry toner.

FIG. 2 shows an example of using positively charged toner. The drying conditions immediately after developing are 110° C. for 3 minutes. In this case the toner does not adhere to the parts of the insulating layer (22) which are electrified to +300 V (the locations other than where the toner image is to be formed), but adheres to the parts electrified to −300 V (the locations where the toner image is to be formed), forming a toner image 24 on the insulating layer (22).

FIG. 3 shows a metal layer-covering step according to the first invention. The surface where the toner image (24) has been formed on the insulating layer (22) of the substrate (S) is covered with a metal layer (50) by a physical vapor deposition method.

The physical vapor deposition method, PVD (Physical Vapor Deposition), is a film-forming method using a physical phenomenon in a vacuum, and the process includes sputtering methods (such as DC sputtering, DC magnetron sputtering, RF sputtering and RF magnetron sputtering), vacuum vapor deposition methods (such as resistance heating and electron beam heating), and ion plating methods (such as activated reactive vapor deposition and high-density plasma-assisted vapor deposition). When a metal layer is to be formed, it is preferred to use DC magnetron sputtering or vacuum vapor deposition from the viewpoint of the film-forming speed.

The metal layer-covered surface may also be surface-modified by plasma treatment, for example, prior to forming the metal layer film.

FIG. 3 shows an example of using DC magnetron sputtering as the physical vapor deposition method. A copper target was set as the cathode of the DC magnetron sputtering device, and the substrate (S) was mounted in the substrate holder. After evacuating the film-forming chamber to 10⁻⁴ Pa, argon gas was introduced to adjust the pressure to 0.2 Pa. And then applying a voltage to the cathode did sputtering, and then the vacuum of the film-forming chamber was broken and the substrate (S) was removed. The toner image (24) on the insulating layer (22) and the surface of the insulating layer (22) without the toner image were both covered with a copper layer (50).

FIG. 4 shows a toner-removing step according to the first invention. The toner image (24) on the substrate (S) is removed together with the metal layer (50) on the toner image. This leaves the metal layer (50) directly covering the insulating layer (22), thus forming a metal image.

In the example of FIG. 4, the toner image was removed by dipping in methanol for 1 minute while applying ultrasonic wave vibration, after which the substrate (S) was washed with water for 1 minute.

The copper image formed on the substrate (S) had a thickness of 100 nm, a line width of 50 μm and a line spacing of 50 to 150 μm.

If necessary, the metal image formed by this method may be subjected to electroless plating treatment, or to both electroless plating treatment and electroplating treatment, laminating metals of the same type or different types onto the formed metal image. By carrying out electroless plating treatment or both electroless plating treatment and electroplating treatment it is possible to improve the properties such as strength and conductivity of the entire metal image including the laminated sections.

### Second Invention

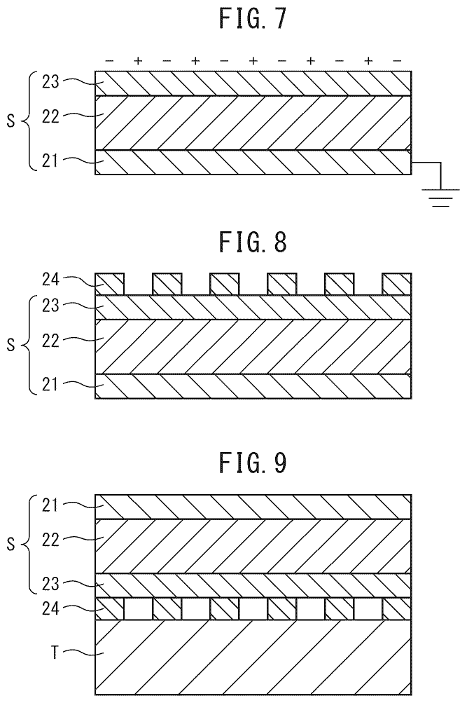

FIG. 7 shows an electrostatic pattern-forming step according to the second invention, in a state with an electrostatic pattern formed and held on the release layer (23) of the substrate (S).

The substrate (S) is formed of a conductive layer (21) serving as the electrode in the electrostatic pattern-forming step, an insulating layer (22), and a release layer (23).

The insulating layer (22) must have a high electrical insulating property since it must hold the electrostatic pattern. The insulating layer (22) used may be a molded article of a polyimide, polycarbonate, PET (polyethylene terephthalate), cycloolefin polymer, cycloolefin copolymer or fluorine-based resin. The lower limit for the thickness of the insulating layer (22) is preferably 1.5 μm or greater from the viewpoint of electrical insulating properties during formation of the electrostatic pattern and during the period of holding the electrostatic pattern, and it is preferably 5 μm or greater from the viewpoint of handling. The upper limit for the thickness of the insulating layer (22) is preferably 200 μm or smaller. If the thickness of the insulating layer (22) exceeds 200 μm the stiffness will increase, making it difficult for the toner image (24) on the substrate (S) and substrate (T) to closely bond and toner transfer.

The release layer (23) is provided on the insulating layer (22) in order to facilitate transfer of the toner image (24) on the substrate (S) onto the substrate (T). A thin-film of a silicone-based resin, fluorine-based resin, olefin-based resin or melamine-based resin formed by a coating method, for example, may be used as the release layer (23). The thickness of the release layer (23) is preferably 0.03 to 0.4 μm.

Since it is sufficient for the conductive layer (21) to carry out the role of providing an electric field in the electrostatic pattern-forming step, or of stabilizing the electrified electrical charge on the release layer (23), it may be constructed of any material that is conductive, such as metal, a conductive oxide, carbon, graphite or a conductive polymer.

The conductive layer (21) is situated on the opposite side of the insulating layer (22) from the release layer (23). The conductive layer (21) can perform the aforementioned role if it is contact bonded with the insulating layer (22), but handling during the electrostatic pattern-forming step and developing step will be facilitated if it is formed integrally with the release layer (23) and insulating layer (22). The release layer (23), insulating layer (22) and conductive layer (21) can be integrated by forming the conductive layer (21) by a method of sputtering a metal film or conductive oxide film, a method of coating a conducting polymer film or a method of laminating a metal foil, on the opposite side from the release layer (23) side of the insulating layer (22). The release layer (23), insulating layer (22) and conductive layer (21) can also be integrated, conversely, by forming the insulating layer (22) and release layer (23) by a coating method on the conductive layer (21) which is made of a metal foil. Alternatively, a conductive layer-attached sheet provided with a conductive layer (21) such as a metal film, conductive oxide film or conducting polymer film on an insulating material sheet may be laminated onto the opposite side from the release layer (23) side of the insulating layer (22), using a pressure-sensitive adhesive layer, to integrate the release layer (23), insulating layer (22) and the conductive layer (21).

FIG. 12 is an example of an electrostatic pattern-forming step according to the second invention. This method applies a high definition electrostatic printing method previously proposed by the present inventors (see Japanese Patent Application No. 2018-188998). An original plate (10) having a plate layer (12) (which has built-in a letterpress, an intaglio plate, or a gravure plate pattern) (FIG. 12 shows an example of intaglio at locations forming a toner image), and a first electrode (11), and a substrate (S) having a release layer (23), insulating layer (22) and a conductive layer (21) as a second electrode, are used to closely bond the plate layer (12) of the original plate (10) with the release layer (23) of the substrate (S), and a voltage sufficient to cause discharge in the space between the pattern of the plate layer (12) and the release layer (23) is applied between the first electrode (11) of the original plate (10) and the second electrode (21) of the substrate (S), thereby forming an electrostatic pattern corresponding to the pattern of the plate layer (12) on the release layer (23).

The condition of discharge in the space can be calculated by Paschen's law. The discharge starting voltage for a space of 8 μm or greater, assumed to be represented linearly, is approximated by the following formula where space: d (μm), space discharge starting voltage: Vb.

$$Vb = 312 + 6.2 d \qquad ( 1 )$$

The space (space between the pattern of the plate layer (12) and the release layer (23)) is 20 μm and the discharge starting voltage is 436 V. In other words, if an external voltage of 436 V or higher is applied to the space, discharge takes place and ions are generated. The generated ions are affected by the electric field, with positive ions migrating toward the negative electrode and negative ions migrating toward the positive electrode. The release layer (23) is electrified by the ions, acting in a direction to weaken the electric field in the space. Discharge is complete when the voltage applied to the space reaches a discharge starting voltage of 436 V.

In the example shown in FIG. 12, the insulating layer (22) is a PET layer with a thickness of 25 μm and a relative permittivity of 3.2, so that converting to air thickness yields 25+3.2=7.8. The thickness of the release layer (23) is smaller than 0.5 μm and can therefore be essentially ignored. For this example, preliminary charging treatment was carried out at +300 V on the entire surface of the release layer (23). The substrate (S) was firmly and closely bonded to the original plate (10) by the preliminary charging treatment. With the plate layer (12) and release layer (23) in a closely bonded state, and using the second electrode (21) as ground potential, a voltage was applied to −723 V on the first electrode (11). The voltage applied to a space of 20 μm is (723+300)×20÷(20+7.8) V=736 V. Since this is greater than the discharge starting voltage of 436 V for a 20 μm space as obtained from formula (1), discharge ions are produced in the space, the negative ions migrating toward the electrode (21) and electrifying the release layer (23), while the positive ions flow to the electrode (11). When the release layer (23) is electrified to −(736−436)=−300 V, the electric field in the space reaches a discharge starting voltage of 436 V, and discharge therefore stops. When the applied power is then switched OFF bringing the electrode 21 to 0 V, and the substrate (S) is subsequently released from the original plate (10), an electrostatic pattern is created on the release layer (23) as the parts corresponding to the voids in the intaglio (the sections forming the toner image) are electrified to −300 V, while the other parts are electrified to +300 V. The electrode (21) is brought to 0 V before releasing in order to produce a condition that prevents discharge upon release, over all parts of the surface.

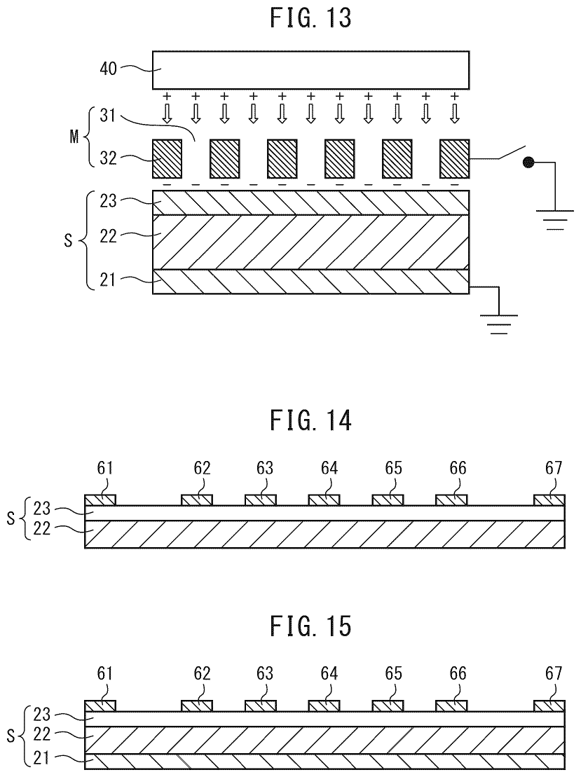

FIG. 13 shows another example of an electrostatic pattern-forming step according to the second invention. This method applies an electrostatic printing method previously proposed by the present inventors (see Japanese Patent Application No. 2021-132875). A mask sheet (M) comprising a molded article consisting of only a conductive material, or a laminated body consisting of an insulating material and a conductive material, and provided with a specified ion permeable opening, is used with a substrate (S) having a release layer (23), an insulating layer (22) and a conductive layer (21) as a back electrode, closely bonding together the mask sheet (M) and the release layer (23) of the substrate (S), conducting ion irradiation through the mask sheet (M), and then releasing the mask sheet (M) from the substrate (S), to form an electrostatic pattern corresponding to the ion-permeable opening and ion shielding part of the mask sheet (M) on the release layer (23) of the substrate (S).

In the example of FIG. 13, the conductive layer (21) serving as the back electrode is closely bonded to the opposite side from the release layer (23) side of the insulating layer (22), with the conductive layer (21) grounded. Before closely bonding the mask sheet (M) with the release layer (23), the entire surface of the release layer (23) is subjected to preliminary charging treatment at −300 V. Preliminary charging treatment causes the mask sheet (M) to be firmly and closely bonded to the release layer (23). Ion irradiation was carried out on the release layer (23) through the mask sheet (M) by ion irradiation means (40) while closely bonding the mask sheet (M) provided with an ion-permeable opening (31). After ion irradiation, the ion irradiation part (corresponding to the ion-permeable opening (31) of the mask sheet (M)) of the release layer (23) and the mask sheet (M) surface was electrified to +300 V. The mask sheet (M) was released from the release layer (23) while grounded. This produced an electrostatic pattern with the ion irradiation part of the release layer (23) (the location other than where the toner image will be formed) electrified to +300 V and the non-ion irradiation part of the release layer (23) (the location where the toner image will be formed) electrified to −300 V.

FIG. 8 shows a developing step according to the second invention. The electrostatic pattern formed by the electrostatic pattern-forming step is developed with charged particles known as toner. According to the invention, the toner image must be removed in the final step, together with the metal layer on it, and therefore the material is selected in consideration of the solution to be used for removal (an aqueous alkali solution or organic solvent). For example, if the toner is a polyvinyl acetate-based material, the selected solvent may be methanol.

The toner used may also be liquid toner for electrophotography as previously proposed by the present inventors (see Japanese Patent Application No. 2019-209237). Liquid toner is advantageous for formation of higher-resolution toner images than with dry toner.

FIG. 8 shows an example of using positively charged toner. The drying conditions immediately after developing are 110° C. for 3 minutes. In this case the toner does not adhere to the parts of the release layer (23) which are electrified to +300 V (the locations other than where the toner image is to be formed), but adheres to the parts electrified to −300 V (the locations where the toner image is to be formed), forming a toner image (24) on the release layer (23).

FIG. 9 is a diagram illustrating a toner transfer step according to the second invention. After the toner image (24) has been closely bonded to the substrate (T), heat and pressure are applied to transfer the toner image (24) onto the substrate (T).

In the example of FIG. 9, the toner image and substrate (T) in a closely bonded state were passed between nip rolls with a surface temperature of 110° C., to transfer the toner image onto the substrate (T). The substrate (T) may be composed of any material that has surface properties (surface roughness and wetness index) and heat resistance necessary for adhesion of toner images. Examples include molded articles and laminated bodies of materials such as various types of plastics, glass, glass epoxy resins, ceramics or metals. For improved adhesion with the toner image, the substrate (T) may be subjected to surface treatment (such as plasma treatment, corona treatment or adhesive layer coating).

FIG. 9 shows an example where the substrate (T) used is a glass plate with a thickness of 0.5 mm.

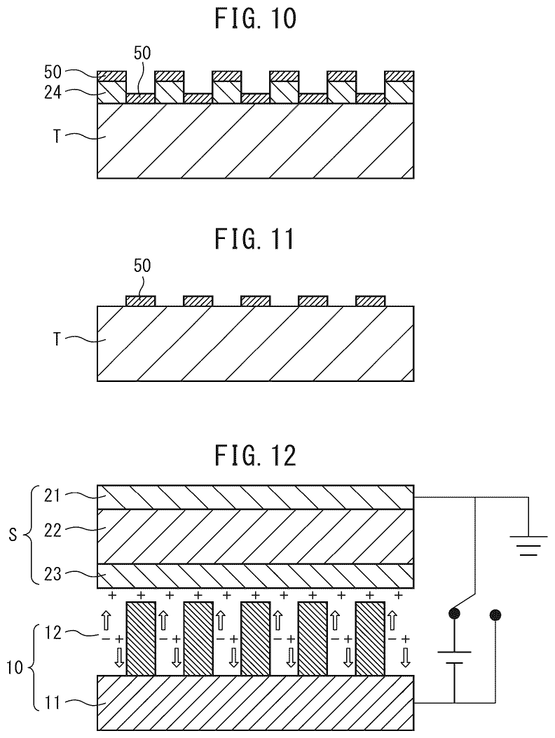

FIG. 10 shows a metal layer-covering step according to the second invention. The surface where the toner image (24) has been transferred onto the substrate (T) is covered with a metal layer (50) by a physical vapor deposition method.

The physical vapor deposition method, PVD (Physical Vapor Deposition), is a film-forming method using a physical phenomenon in a vacuum, and the process includes sputtering methods (such as DC sputtering, DC magnetron sputtering, RF sputtering and RF magnetron sputtering), vacuum vapor deposition methods (such as resistance heating and electron beam heating), and ion plating methods (such as activated reactive vapor deposition and high-density plasma-assisted vapor deposition). When a metal layer is to be formed, it is preferred to use DC magnetron sputtering or vacuum vapor deposition from the viewpoint of the film-forming speed. The metal layer-covered surface may also be surface-modified by plasma treatment, for example, prior to forming the metal layer film.

FIG. 10 shows an example of using DC magnetron sputtering as the physical fabrication process. A copper target was set as the cathode of the DC magnetron sputtering device, and the substrate (T) was mounted in the substrate holder. After evacuating the film-forming chamber to 10⁻⁴ Pa, argon gas was introduced to adjust the pressure to 0.2 Pa. And then applying a voltage to the cathode did sputtering, and then the vacuum of the film-forming chamber was broken and the substrate (T) was removed. The toner image (24) on the substrate (T) and the surface of the substrate (T) without the toner image were both covered with a copper layer (50).

FIG. 11 shows a toner-removing step according to the second invention. The toner image (24) on the substrate T is removed together with the metal layer (50) on the toner image. This leaves the metal layer (50) directly covering the substrate (T), thus forming a metal image.

In the example of FIG. 11, the toner image was removed by dipping in methanol for 1 minute while applying ultrasonic wave vibration, after which the substrate was washed with water for 1 minute.

The copper image formed on the substrate (T) had a thickness of 100 nm, a line width of 50 μm and a line spacing of 50 to 150 μm.

If necessary, the metal image formed by this method may be subjected to electroless plating treatment, or to both electroless plating treatment and electroplating treatment, laminating metals of the same type or different types onto the formed metal image. By carrying out electroless plating treatment or both electroless plating treatment and electroplating treatment it is possible to improve the properties such as strength and conductivity of the entire metal image including the laminated sections.

### Third Invention

FIG. 14 is a diagram illustrating an example of a resin image-forming step according to the third invention.

In FIG. 14, resin images 61 to 67 are formed on the release layer (23) of the substrate (S) by a printing method.

The substrate (S) is composed of an insulating layer (22) and a release layer (23) provided on one side of the insulating layer (22).

The insulating layer (22) is a film, sheet or composite composed of a thermoplastic resin. For example, a film, sheet or composite made of amorphous polyethylene terephthalate (A-PET), glycol-modified polyethylene terephthalate (G-PET), polycarbonate (PC), acrylonitrile-butadiene-styrene copolymer (ABS), polystyrene (PS), polymethyl methacrylate (PMMA), polyvinyl chloride (PVC) or polypropylene (PP) may be suitably used. Most preferred among these are films or sheets made of A-PET, G-PET or PC. There are no particular restrictions on the thickness of the insulating layer (22), which may be decided in light of the conditions for the resin image transfer step.

The release layer (23) is provided on the insulating layer (22) in order to facilitate transfer of the resin images (61) to (67) on the substrate (S) onto the substrate (T). A thin-film of a silicone-based resin, fluorine-based resin, olefin-based resin or melamine-based resin formed by a coating method, for example, may be used as the release layer (23). The thickness of the release layer (23) is preferably 0.03 to 0.4 μm.

The printing method used may be screen printing, gravure offset printing or ink-jet printing.

Ink containing the resin for formation of a resin image is used in the printing method. According to the invention, the resin images (61) to (67) must be removed in the final step, together with the metal layer on them, and therefore both the material of the resin for formation of the resin images and the material of the solution (an aqueous alkali solution or organic solvent) for removal are selected. For example, if the resin for formation of the resin images is a material composed mainly of polyvinyl acetate, then methanol may be selected as the solution to be used for removal.

FIG. 15 shows another example of a resin image-forming step according to the third invention.

In FIG. 15, first an electrostatic pattern is formed on the release layer (23), after which the electrostatic pattern is developed with charged particles known as toner to form resin images (61) to (67) on the release layer (23).

The substrate (S) is formed of a conductive layer (21) serving as the electrode during electrostatic pattern formation, an insulating layer (22) and a release layer (23).

The constructions of the insulating layer (22) and release layer (23) are the same as in FIG. 14.

Since it is sufficient for the conductive layer (21) to carry out the role of providing an electric field during electrostatic pattern formation, or of stabilizing the electrified electrical charge on the release layer (23), it may be constructed of any material that is conductive, such as metal, a conductive oxide, carbon, graphite or a conductive polymer.

The conductive layer (21) is situated on the opposite side of the insulating layer (22) from the release layer (23). The conductive layer (21) can perform the aforementioned role if it is contact bonded with the insulating layer (22), but handling during electrostatic pattern formation and development will be facilitated if it is formed integrally with the release layer (23) and insulating layer (22). The release layer (23), insulating layer (22) and conductive layer (21) can be integrated by forming the conductive layer (21) by a method of sputtering a metal film or conductive oxide film or a method of coating a conducting polymer film, on the opposite side from the release layer (23) side of the insulating layer (22). Alternatively, a conductive layer-attached sheet provided with a conductive layer (21) such as a metal film, conductive oxide film or conducting polymer film on an insulating material sheet may be laminated onto the opposite side from the release layer (23) side of the insulating layer (22), using a pressure-sensitive adhesive layer, to integrate the release layer (23), insulating layer (22) and the conductive layer (21).

An example of an electrostatic pattern forming method will now be described. This method applies a high definition electrostatic printing method previously proposed by the present inventors (see Japanese Patent Application No. 2018-188998). An original plate having a plate layer (which has built-in a letterpress, an intaglio plate, or a gravure plate pattern) and a first electrode, and a substrate (S) having a release layer (23), insulating layer (22) and a conductive layer (21) as a second electrode, are used to closely bond the plate layer of the original plate with the release layer (23) of the substrate (S), and a voltage sufficient to cause discharge in the space between the pattern of the plate layer and the release layer (23) is applied between the first electrode of the original plate and the second electrode of the substrate (S), thereby forming an electrostatic pattern corresponding to the pattern of the plate layer on the release layer (23) of the substrate (S).

Another example of an electrostatic pattern forming method will now be described. This method applies an electrostatic printing method previously proposed by the present inventors (see Japanese Patent Application No. 2021-132875). A mask sheet comprising a molded article consisting of only a conductive material, or a laminated body consisting of an insulating material and a conductive material, and provided with a specified ion permeable opening, is used with a substrate (S) having a release layer (23), an insulating layer (22) and a conductive layer (21) as a back electrode, closely bonding together the mask sheet and the release layer (23) of the substrate (S), conducting ion irradiation through the mask sheet, and then releasing the mask sheet from the substrate (S), to form an electrostatic pattern corresponding to the ion-permeable opening and ion shielding part of the mask sheet on the release layer (23) of the substrate (S).

The electrostatic pattern is then developed with charged particles known as toner to form resin images (61) to (67) on the release layer (23). According to the invention, the resin images (61) to (67) must be removed in the final step, together with the metal layer on them, and therefore both the material of the resin for composing the toner and the material of the solution (an aqueous alkali solution or organic solvent) for removal are selected. For example, if the resin composing the toner is a material composed mainly of polyvinyl acetate, then methanol may be selected as the solution to be used for removal.

The toner used may also be liquid toner for electrophotography as previously proposed by the present inventors (see Japanese Patent Application No. 2019-209237). Liquid toner is advantageous for formation of higher-resolution resin images than with dry toner. The drying conditions immediately after developing are 110° C. for 3 minutes.

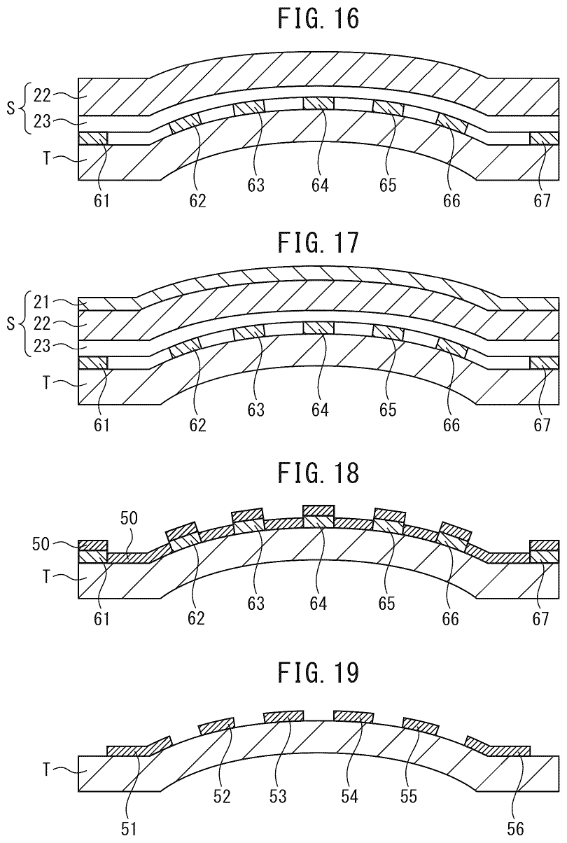

FIG. 16 shows an example of a resin image transfer step for FIG. 14, and FIG. 17 shows the same for FIG. 15. Molding of the substrate (S) on which resin images (61) to (67) had been formed was carried out using the substrate (T) itself as the molding die, for close bonding with the substrate (T), thereby transferring the resin images (61) to (67) onto the substrate (T). The method of molding the substrate (S) may be vacuum molding or pneumatic molding. Vacuum molding is a method of molding by vacuum suction with a heat-softened substrate material against the die. Pneumatic molding is a method of molding with a heat-softened substrate material closely adhering to the die by pressure. Vacuum molding or pneumatic molding is selected depending on the type and thickness of the substrate material.

The examples shown in FIG. 16 and FIG. 17 each used a substrate (S) made of polycarbonate having an insulating layer thickness of 0.3 mm and a substrate (T) made of glass that was hemispherically curved at the center with a flat periphery having a thickness of 0.5 mm, with vacuum molding of the substrate (S) to cause close bonding with the substrate (T), thereby transferring the resin images (61) to (67) onto the substrate (T).

The substrate (T) must be heat-resistant since it is to serve as the die for molding of the substrate (S). It may be composed of any material that has the surface properties (surface roughness and wetness index) necessary for adhesion of resin images. Examples include molded articles or laminated bodies of materials such as thermosetting resins, UV curable resins, glass and ceramics. For improved adhesion with the resin images, the substrate (T) may be subjected to surface treatment (such as plasma treatment, corona treatment or adhesive layer coating).

FIG. 18 shows a metal layer-covering step according to the third invention. The surface where the resin images (61) to (67) have been transferred onto the substrate (T) is covered with a metal layer (50) by a physical vapor deposition method.

The physical vapor deposition method, PVD (Physical Vapor Deposition), is a film-forming method using a physical phenomenon in a vacuum, and the process includes sputtering methods (such as DC sputtering, DC magnetron sputtering, RF sputtering and RF magnetron sputtering), vacuum vapor deposition methods (such as resistance heating and electron beam heating), and ion plating methods (such as activated reactive vapor deposition and high-density plasma-assisted vapor deposition). When a metal layer is to be formed, it is preferred to use DC magnetron sputtering or vacuum vapor deposition from the viewpoint of the film-forming speed.

The metal layer-covered surface may also be surface-modified by plasma treatment, for example, prior to forming the metal layer film.

FIG. 18 shows an example of using DC magnetron sputtering as the physical vapor deposition method. A copper target was set as the cathode of the DC magnetron sputtering device, and the substrate (T) was mounted in the substrate holder. After evacuating the film-forming chamber to 10⁻⁴ Pa, argon gas was introduced to adjust the pressure to 0.2 Pa. And then applying a voltage to the cathode did sputtering, and then the vacuum of the film-forming chamber was broken and the substrate (T) was removed. The resin images (61) to (67) on the substrate (T) and the surface of the substrate (T) without the resin images were both covered with a copper layer (50).

FIG. 19 shows a resin image-removing step according to the third invention. The resin images (61) to (67) on the substrate (T) are removed together with the metal layer (50) on the resin images. This leaves a metal layer (50) directly covering the substrate (T), thus forming metal images (51) to (56).

In the example of FIG. 19, the resin images (61) to (67) were removed together with the metal layer (50) on the resin images, by dipping in methanol for 1 minute while applying ultrasonic wave vibration, after which the substrate was washed with water for 1 minute.

The copper images (51) to (56) formed on the substrate (T) had thicknesses of 100 nm and line widths of 50 μm, with no wire breakage at the hemispherical section or no wire breakage at the sections moving out flat from the hemispherical surface.

If necessary, the metal image formed by this method may be subjected to electroless plating treatment, or to both electroless plating treatment and electroplating treatment, laminating metals of the same type or different types onto the formed metal image. By carrying out electroless plating treatment or both electroless plating treatment and electroplating treatment it is possible to improve the properties such as strength and conductivity of the entire metal image including the laminated sections.

### INDUSTRIAL APPLICABILITY

The present invention can be used in the field of electronics, as well as in numerous industrial fields such as commercial printing, business cards or cosmetic containers.

### REFERENCE SIGNS LIST

10: Original plate
11: First electrode
12: Plate layer
21: Conductive layer
22: Insulating layer
23: Release layer
24: Toner image
31: Ion-permeable opening
32: Ion shielding part
40: Ion irradiation means
50: Metal layer
51: Metal image
52: Metal image
53: Metal image
54: Metal image
55: Metal image
56: Metal image
61: Resin image
62: Resin image
63: Resin image
64: Resin image
65: Resin image
66: Resin image
67: Resin image
S: Substrate(S)
T: Substrate (T)
M: Mask sheet

1. A metal image forming method, comprising:
(1) forming an electrostatic pattern on the insulating layer of a substrate (S) having an insulating layer and a conductive layer,
(2) developing the electrostatic pattern with charged particles known as toner, to form a toner image on the insulating layer of the substrate (S),
(3) covering the toner image-formed surface of the substrate (S) with a metal layer by a physical vapor deposition method, and
(4) removing the toner image together with the metal layer on the toner image.

2. The metal image forming method according to claim 1, wherein in step (1), an original plate having a plate layer (which has built-in a letterpress, an intaglio plate, or a gravure plate pattern) and a first electrode, and a substrate (S) having an insulating layer and a conductive layer as a second electrode, are used, closely bonding the plate layer of the original plate with the insulating layer of the substrate (S), and a voltage sufficient to cause discharge in the space between the pattern of the plate layer and the insulating layer is applied between the first electrode of the original plate and the second electrode of the substrate (S), thereby forming an electrostatic pattern corresponding to the pattern of the plate layer on the insulating layer of the substrate (S).

3. The metal image forming method according to claim 1, wherein in step (1), a mask sheet comprising a molded article consisting of only a conductive material, or a laminated body consisting of an insulating material and a conductive material, and provided with a specified ion permeable opening, is used with a substrate (S) having an insulating layer and a conductive layer as a back electrode, closely bonding together the mask sheet and the insulating layer of the substrate (S), conducting ion irradiation through the mask sheet, and then releasing the mask sheet from the substrate (S), to form an electrostatic pattern corresponding to the ion-permeable opening and ion shielding part of the mask sheet on the insulating layer of the substrate (S).

4. The metal image forming method according to claim 3, wherein the ion irradiation means is an ion irradiation system using corona discharge.

5. A metal image forming method, comprising:
(1) forming an electrostatic pattern on the release layer of a substrate (S) having a release layer, an insulating layer and a conductive layer,
(2) developing the electrostatic pattern with charged particles known as toner, to form a toner image on the release layer of the substrate (S),
(3) transferring the toner image onto the substrate (T),
(4) covering the toner image-transferred surface of the substrate (T) with a metal layer by a physical vapor deposition method, and
(5) removing the toner image together with the metal layer on the toner image.

6. The metal image forming method according to claim 5, wherein in step (1) of claim 5, an original plate having a plate layer (which has built-in a letterpress, an intaglio plate, or a gravure plate pattern) and a first electrode, and a substrate (S) having a release layer, an insulating layer and a conductive layer as a second electrode, are used, closely bonding the plate layer of the original plate with the release layer of the substrate (S), and a voltage sufficient to cause discharge in the space between the pattern of the plate layer and the release layer is applied between the first electrode of the original plate and the second electrode of the substrate (S), thereby forming an electrostatic pattern corresponding to the pattern of the plate layer on the release layer of the substrate (S).

7. The metal image forming method according to claim 5, wherein in step (1) of claim 5, a mask sheet comprising a molded article consisting of only a conductive material, or a laminated body consisting of an insulating material and a conductive material, and provided with a specified ion permeable opening, is used with a substrate (S) having a release layer, an insulating layer and a conductive layer as a back electrode, closely bonding together the mask sheet and the release layer of the substrate (S), conducting ion irradiation through the mask sheet, and then releasing the mask sheet from the substrate (S), to form an electrostatic pattern corresponding to the ion-permeable opening and ion shielding part of the mask sheet on the release layer of the substrate (S).

8. The metal image forming method according to claim 7, wherein the ion irradiation means is an ion irradiation system using corona discharge.

9. A metal image forming method, comprising:
(1) forming a resin image on a flat substrate (S),
(2) molding the substrate (S) so that the resin image surface of the substrate (S) is closely bonded to the substrate (T) having all or part of curved surface, to transfer the resin image onto the substrate (T),
(3) covering the resin image-transferred surface of the substrate (T) with a metal layer by a physical vapor deposition method, and
(4) removing the resin image together with the metal layer on the resin image.

10. The metal image forming method according to claim 9, wherein in step (1) of claim 9, the flat substrate (S) is made of an insulating layer composed of a thermoplastic resin film or sheet, or a composite thereof, and a release layer formed on one side of the insulating layer, and a resin image is formed on the release layer by a printing method.

11. The metal image forming method according to claim 9, wherein in step (1) of claim 9, the flat substrate (S) is made of an insulating layer composed of a thermoplastic resin film or sheet, or a composite thereof, a release layer formed on one side of the insulating layer, and a conductive layer provided on the opposite side from the release layer, and an electrostatic pattern is first formed on the release layer, after which the electrostatic pattern is developed by charged particles known as toner to form a resin image on the release layer.

12. The metal image forming method according to claim 11, wherein an original plate having a plate layer (which has built-in a letterpress, an intaglio plate, or a gravure plate pattern) and a first electrode, and a substrate (S) having a release layer, an insulating layer and a conductive layer as a second electrode, are used, closely bonding the plate layer of the original plate with the release layer of the substrate (S), and a voltage sufficient to cause discharge in the space between the pattern of the plate layer and the release layer is applied between the first electrode of the original plate and the second electrode of the substrate (S), thereby forming an electrostatic pattern corresponding to the pattern of the plate layer on the release layer of the substrate (S).

13. The metal image forming method according to claim 11, wherein a mask sheet comprising a molded article consisting of only a conductive material, or a laminated body consisting of an insulating material and a conductive material, and provided with a specified ion permeable opening, is used with a substrate (S) having a release layer, an insulating layer and a conductive layer as a back electrode, closely bonding together the mask sheet and the release layer of the substrate (S), conducting ion irradiation through the mask sheet, and then releasing the mask sheet from the substrate (S), to form an electrostatic pattern corresponding to the ion-permeable opening and ion shielding part of the mask sheet on the release layer of the substrate (S).
